(19) United States
(12) Patent Application Publication
(10) Pub. No.: US 2015/0325685 A1
(43) Pub. Date: Nov. 12, 2015

(54) Power Semiconductor Device with Low RDSON and High Breakdown Voltage

(71) Applicant: International Rectifier Corporation, EI Segundo, CA (US)

(72) Inventors: Timothy D. Henson, Mount Shasta, CA (US); Ling Ma, Redondo Beach, CA (US); Kapil Kelkar, Torrance, CA (US); Ljubo Radic, Torrance, CA (US); Hugo Burke, Llantrisant (GB); David Paul Jones, Penarth (GB)

(21) Appl. No.: 14/685,257

(22) Filed: Apr. 13, 2015

Related U.S. Application Data
(60) Provisional application No. 61/989,990, filed on May 7, 2014.

(51) Int. Cl. H01L 29/66; H01L 21/306; H01L 21/28; H01L 29/78; H01L 29/423

(52) U.S. Cl. CPC H01L 29/66734; H01L 29/7813; H01L 29/4236; H01L 21/28008; H01L 21/30604

(57) ABSTRACT

A semiconductor structure is disclosed. The semiconductor structure includes a trench having substantially parallel trench sidewalls, and a tapered dielectric liner in the trench. The tapered dielectric liner includes slanted dielectric sidewalls. A conductive filler is enclosed by the slanted dielectric sidewalls in the trench.

The present application claims the benefit of and priority to U.S. Provisional Patent Application Ser. No. 61/989,990, filed on May 7, 2014, and entitled “Semiconductor Bodies Having Trenches with Tapered Dielectric Liners.” The disclosure in this provisional application is hereby incorporated fully by reference into the present application.

### BACKGROUND

Trench power semiconductor devices, such as trench power MOSFETs (metal oxide semiconductor field effect transistors) or power diodes, exhibit vertical current conduction through the semiconductor device. On-state resistance (i.e., R_{Dson}) and breakdown voltage are major design considerations of a trench power semiconductor device. For example, it is desirable for a trench power MOSFET to have a low on-state resistance (i.e., R_{DSon}) in its on-state, and be able to withstand a high drain-to-source voltage during its off-state (i.e., a high reverse voltage blocking capability or a high breakdown voltage).

One technique for improving the breakdown voltage of a trench power MOSFET involves embedding a field plate electrode in a drift region of the trench power MOSFET, where the field plate electrode is enclosed by a dielectric layer in a trench and electrically connected to a fixed electrical potential, such as a gate or source potential in the trench power MOSFET. The field plate electrode may be formed by depositing a conductive filler over a dielectric material along the sidewalls of the trench. Because the dielectric material typically has a uniform thickness along the sidewalls of the trench, the deposition process of the conductive filler usually leads to the formation of voids or other defects in the field plate electrode. These defects in the field plate electrode can have a significant adverse impact on the reverse voltage blocking capability of the field plate electrode. Also, a dielectric liner having a uniform thickness along sidewalls of a trench can undesirably result in large cell pitch and contribute to the on-state resistance.

Accordingly, there is a need to overcome the drawbacks and deficiencies in the art by providing a power semiconductor device, such as a power MOSFET, with a reduced on-state resistance without compromising the breakdown voltage of the power semiconductor device.

### SUMMARY

The present disclosure is directed to a power semiconductor device with low R_{DSON} and high breakdown voltage, substantially as shown in and/or described in connection with at least one of the figures, and as set forth in the claims.

### BRIEF DESCRIPTION OF THE DRAWINGS

FIG. 1 illustrates a cross-sectional view of a portion of an exemplary semiconductor structure, according to an implementation disclosed in the present application.

FIG. 2 shows a flowchart illustrating exemplary methods, according to implementations disclosed in the present application.

FIG. 3 illustrates a cross-sectional view, which includes a portion of an exemplary semiconductor structure, processed according to an implementation disclosed in the present application.

FIG. 4A illustrates a cross-sectional view, which includes a portion of an exemplary semiconductor structure, processed according to an implementation disclosed in the present application.

FIG. 4B illustrates a cross-sectional view, which includes a portion of an exemplary semiconductor structure, processed according to an implementation disclosed in the present application.

FIG. 5A illustrates a cross-sectional view, which includes a portion of an exemplary semiconductor structure, processed according to an implementation disclosed in the present application.

FIG. 5B illustrates a cross-sectional view, which includes a portion of an exemplary semiconductor structure, processed according to an implementation disclosed in the present application.

FIG. 5C illustrates a cross-sectional view, which includes a portion of an exemplary semiconductor structure, processed according to an implementation disclosed in the present application.

FIG. 5D illustrates a cross-sectional view, which includes a portion of an exemplary semiconductor structure, processed according to an implementation disclosed in the present application.

### DETAILED DESCRIPTION

The following description contains specific information pertaining to implementations in the present disclosure. The drawings in the present application and their accompanying detailed description are directed to merely exemplary implementations. Unless noted otherwise, like or corresponding elements among the figures may be indicated by like or corresponding reference numerals. Moreover, the drawings and illustrations in the present application are generally not to scale, and are not intended to correspond to actual relative dimensions.

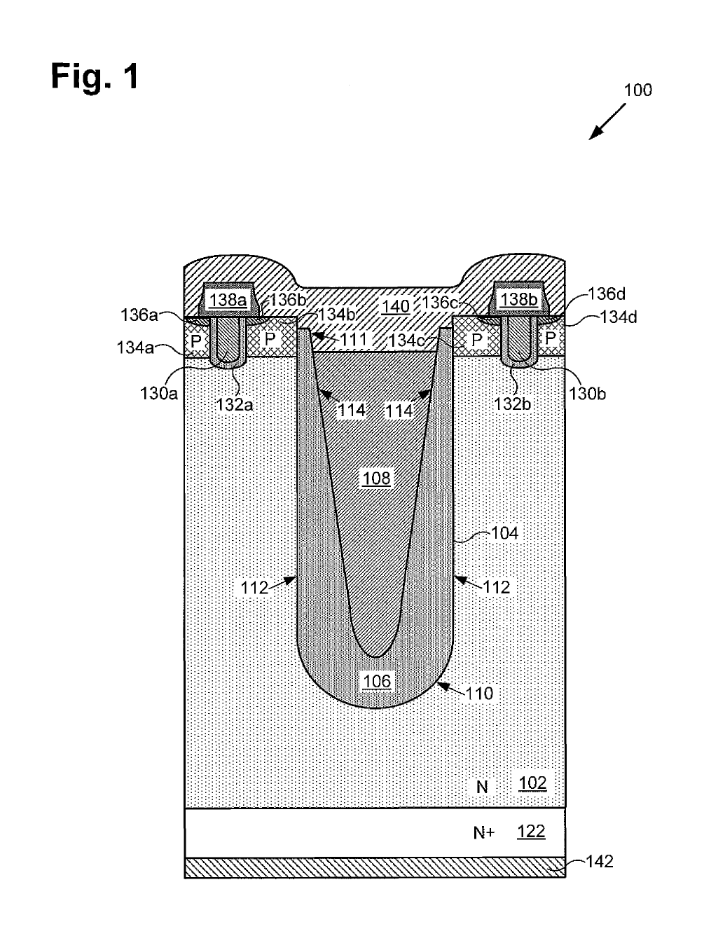

FIG. 1 illustrates a cross-sectional view of a portion of an exemplary semiconductor structure, according to an implementation disclosed in the present application. More particularly, FIG. 1 illustrates a cross-sectional view of a portion of semiconductor structure 100 having at least one power MOSFET, for example. Semiconductor structure 100 includes drift region 102 of a first conductivity (e.g., N type), body regions 134a, 134b, 134c, and 134d (collectively referred to as body region 134) of a second conductivity (e.g., P type) over drift region 102, gate electrodes 130a and 130b respectively surrounded by gate dielectric liners 132a and 132b and extending through body region 134 to drift region 102, source regions 136a, 136b, 136c and 136d of the first conductivity (e.g., N+ type), and drain region 122 of the first conductivity (e.g., N+ type). In other implementations, drift region 102, drain region 122 and source regions 136a-136d can have a P type conductivity, and body regions 134a-134d can have an N type conductivity.

As illustrated in FIG. 1, semiconductor structure 100 further includes trench 104 extending through body region 134 to drift region 102, where tapered dielectric liner 106 is formed in trench 104 and conductive filler 108 is enclosed by tapered dielectric liner 106. Trench 104 includes substantially parallel trench sidewalls 112 and bottom 110. Tapered dielectric liner 106 in trench 104 and have slanted dielectric sidewalls 114 that slope inwards toward bottom 110. As can be seen in FIG. 1, tapered dielectric liner 106 is thinner at top 111 of trench 104 than at bottom 110 of trench 104. Conductive filler 108 is deposited in trench 104 and has a shape conformal to tapered dielectric liner 106. Semiconductor structure 100 also includes dielectric caps 138a and 138b, source contact 140, and drain contact 142.

Many semiconductor devices, such as semiconductor structure 100 of FIG. 1, employ trenches formed in a drift region, such as trench 104 formed in drift region 102. Trenches in a drift region are typically filled with conductive fillers, such as conductive metal or doped polysilicon, which form electrodes of a semiconductor device. The conductive filler is electrically insulated from the drift region by a dielectric liner, such as silicon dioxide. For example, trench 104 in drift region 102 is filled with conductive filler 108, which is electrically insulated from drift region 102 by tapered dielectric liner 106.

However, processing constraints can dictate the shape of the trenches in the drift region. For example, a dielectric liner may be formed in trench 104 by thermally oxidizing drift region 102 or by depositing dielectric material in trench 104. Subsequently, conductive filler can be deposited in trench 104. However, due to processing constraints, it may be required that trench 104 is formed to have trench sidewalls that slope inwards whereas it may be otherwise desirable for the trench sidewalls to be substantially parallel, as are trench sidewalls 112 in semiconductor structure 100. In particular, it may be necessary that the trench sidewalls slope inwards so as to reduce the risk that voids or other defects form when depositing the conductive filler in trench 104.

As illustrated in FIG. 1, trench 104 can have substantially parallel trench sidewalls 112, while tapered dielectric liner 106 has slanted dielectric sidewalls 114 that are not parallel. As a result, tapered dielectric liner 106 has a thick bottom portion at bottom 110 of trench 104, and sidewall portions that become gradually thinner toward top 111 of trench 104. Under reverse bias, a voltage difference between drift region 102 and conductive filler 108 is the greatest at bottom 110 of trench 104, and gradually decreases toward top 111 of trench 104 along trench sidewalls 112. Thus, while the thick bottom portion is required in tapered dielectric liner 106 to withstand the greatest voltage difference (e.g., a full drain-to-source voltage) at bottom 110 of trench 104, a thinner thickness of dielectric liner 106 toward top 111 of trench 104 is sufficient to provide the same reverse voltage blocking capability, since the voltage difference in drift region decreases from drain region 122 toward body region 134 under reverse bias. As such, trench 104 can be made narrower, thereby reducing cell pitch and on-resistance of semiconductor structure 100. The reduced cell pitch can in turn reduce the unit cell area to allow more unit cells to be manufactured in a semiconductor wafer, thereby reducing manufacturing cost.

In accordance with implementations of the present disclosure, trench 104 includes tapered dielectric liner 106, which is thinner at top 111 of trench 104 than at bottom 110 of trench 104. Tapered dielectric liner 106 assists in preventing the formation voids or other defects in depositing conductive filler 108 in trench 104. As illustrated in FIG. 1, tapered dielectric liner 106 further includes outer sidewalls that are substantially parallel. However, in other implementations, the outer sidewalls of tapered dielectric liner 106 can be tapered and may have a different slope than slanted dielectric sidewalls 114. Similarly, trench sidewalls 112 of trench 104 may not be substantially parallel with one another, but still can be substantially parallel to respective ones of the outer sidewalls of tapered dielectric liner 106.

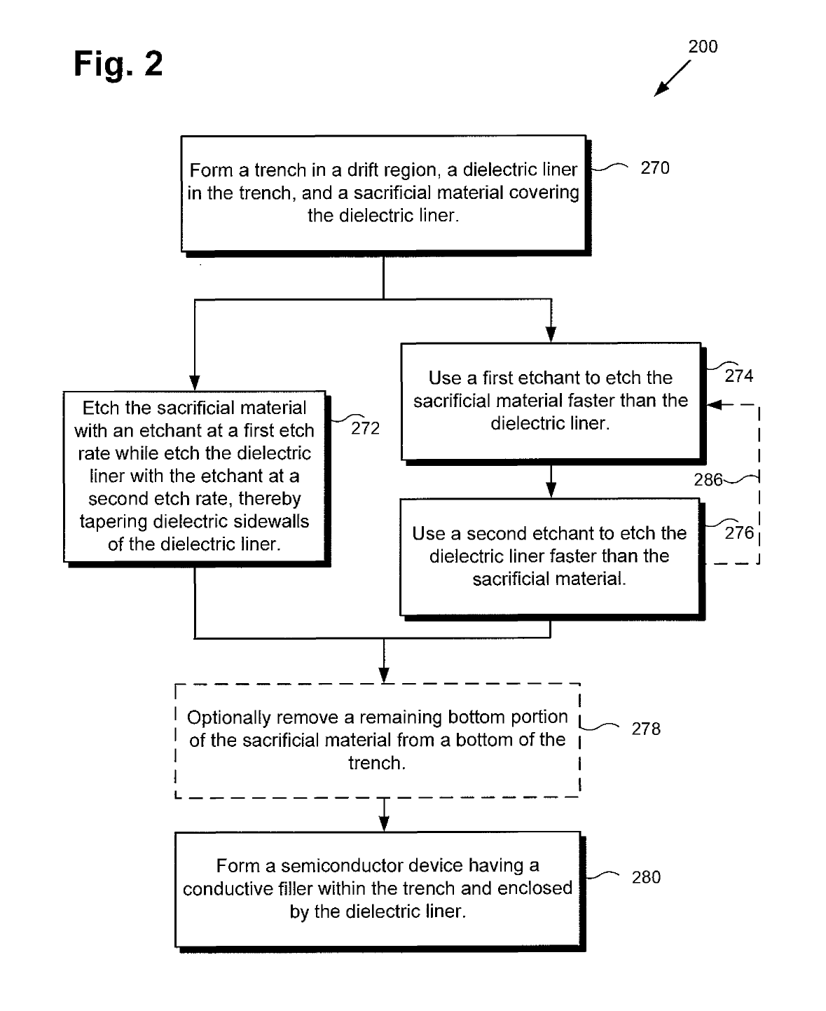

FIG. 2 shows a flowchart illustrating exemplary methods, according to implementations disclosed in the present application. The exemplary methods can be employed in fabrication of semiconductor structure 100 of FIG. 1. The approaches and techniques indicated by flowchart 200 are sufficient to describe at least one implementation of the present disclosure, however, other implementations of the disclosure may utilize approaches and techniques different from those shown in flowchart 200. Furthermore, while flowchart 200 is described with respect to FIGS. 1, 3, 4A, 4B, 5A, 5B, 5C, and 5D, the disclosed inventive concepts are not intended to be limited by specific features shown and described with respect to FIGS. 1, 3, 4A, 4B, 5A, 5B, 5C, and 5D. Furthermore, with respect to the methods illustrated in FIG. 2, it is noted that certain details and features have been left out of flowchart 200 in order not to obscure discussion of inventive features in the present application.

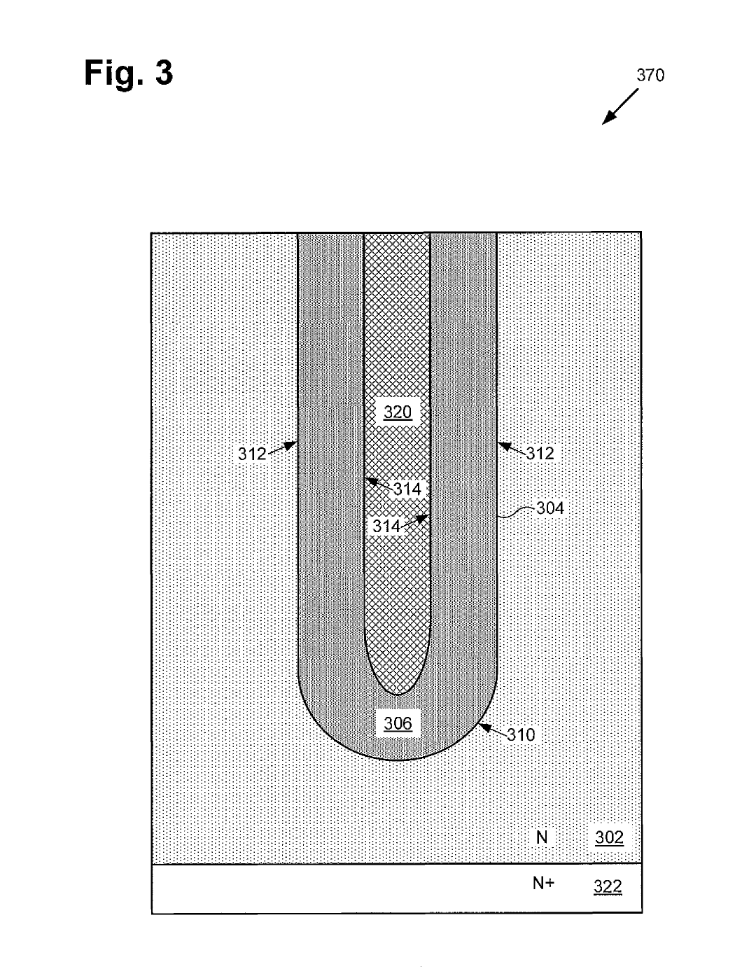

Referring to flowchart 200 of FIG. 2 and to FIG. 3, action 270 of flowchart 200 includes forming a trench (e.g., 304) in a drift region (e.g., 302), a dielectric liner (e.g., 306) in the trench, and a sacrificial material (e.g., 320) covering the dielectric liner. FIG. 3 illustrates a cross-sectional view, which includes a portion of an exemplary semiconductor structure, processed according to an implementation disclosed in the present application. In particular, FIG. 3 shows semiconductor structure 370, which includes drift region 302, trench 304, dielectric liner 306, sacrificial material 320, and drain region 322.

In semiconductor structure 370, drift region 302 is of a first conductivity type (e.g., N type), and includes semiconductor material, such as silicon. Drift region 302 can be formed on drain region 322 of the first conductivity type (e.g., N+ type), such as a silicon substrate. In some implementations, drift region 302 is an epitaxial layer of semiconductor material (e.g., epitaxial silicon) grown on drain region 322.

Although silicon is specified, drift region 302 and/or drain region 322 can include different semiconductor materials, such as various group IV and/or group III-V semiconductor materials. Furthermore, drift region 302 can include various other layers depending on the semiconductor device being fabricated. Also, drift region 302 and/or drain region 322 can include doped semiconductor material, which can vary depending on the semiconductor device being formed. In the present example, drain region 322 is N+ type silicon and drift region 302 is N type silicon, by way of example.

As shown in FIG. 3, trench 304 is formed in drift region 302. Trench 304 can be formed in drift region 302 utilizing any suitable approach. As one example, a mask can be formed over drift region 302 and drain region 322 and can be patterned to expose portions of drift region 302 for etching. Drift region 302 can then be etched so as to form one or more trenches, such as trench 304, in the exposed portions of drift region 302 through the mask. In the present implementation, trench 304 is approximately 6.5 microns deep and 1.6 microns wide, by way of example.

As further shown in FIG. 3, dielectric liner 306 is formed in trench 304. Dielectric liner 306 can be formed in trench 304 utilizing any suitable approach. In one exemplary approach, drift region 302 is thermally oxidized to form dielectric liner 306 as thermal oxide. In other approaches, dielectric liner 306 is deposited over drift region 302 and in trench 304. For example, in the present implementation, dielectric liner 306 includes an oxide, more specifically silicon dioxide, deposited with Tetraethyl Orthosilicate (TEOS). In various implementations, dielectric liner 306 generally includes dielectric material that is suitable for insulating an electrode of a semiconductor device from drift region 302.

Also shown in FIG. 3, sacrificial material 320 is formed covering dielectric liner 306 in trench 304. Sacrificial material 320 can be formed to cover dielectric liner 306 utilizing any suitable approach. In one exemplary approach, sacrificial material 320 is deposited over drift region 302 and dielectric liner 306. Forming sacrificial material 320 covering dielectric liner 306 can fill trench 304, as shown. Sacrificial material 320 includes material that is different than that of dielectric liner 306. In particular, the materials of sacrificial material 320 and dielectric liner 306 are selected such that sacrificial material 320 and dielectric liner 306 can be etched at different etch rates when exposed to a same etchant. Suitable materials for sacrificial material 320 include various organic materials, such as polyamide materials.

After forming sacrificial material 320 covering dielectric liner 306 in trench 304, drift region 302 can be further processed, for example, by performing a planarization, such as a chemical mechanical planarization (CMP), thereby exposing drift region 302 and resulting in semiconductor structure 370 of FIG. 3.

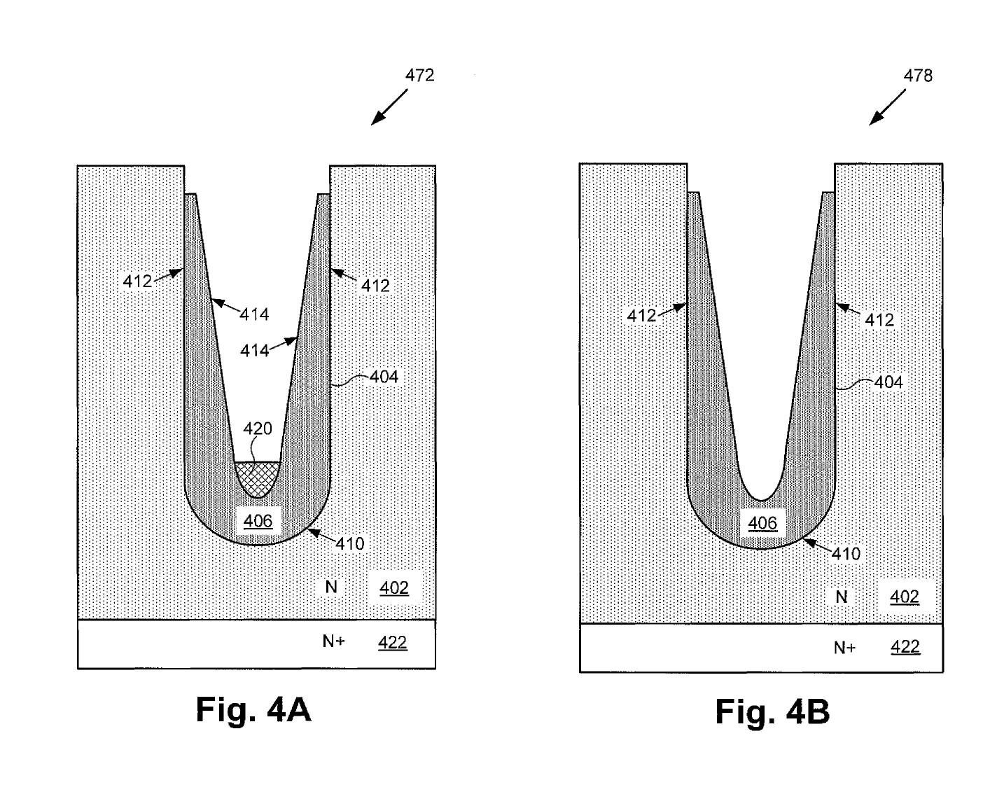

Semiconductor structure 370 of FIG. 3 can be processed utilizing various approaches so as to taper dielectric liner 306. A first approach is shown and described below with respect to FIGS. 2 and 4A.

Referring to flowchart 200 of FIG. 2 and to FIGS. 3 and 4A, action 272 of flowchart 200 includes etching the dielectric liner (e.g., 306) and the sacrificial material (e.g., 320) with a same etchant at different etch rates, thereby tapering dielectric sidewalls (e.g., 314) of the dielectric liner.

FIG. 4A illustrates a cross-sectional view, which includes a portion of an exemplary semiconductor structure, processed according to an implementation disclosed in the present application. In particular, FIG. 4A shows semiconductor structure 472, which includes drift region 402, trench 404, dielectric liner 406, sacrificial material 420, and drain region 422. Semiconductor structure 472, drift region 402, trench 404, dielectric liner 406, sacrificial material 420, and drain region 422 in FIG. 4A can correspond respectively to semiconductor structure 370, drift region 302, trench 304, dielectric liner 306, sacrificial material 320, and drain region 322 after etching dielectric liner 306 and sacrificial material 320 with a same etchant at different etch rates, thereby tapering dielectric sidewalls 314 of dielectric liner 306.

The etching of dielectric liner 306 and sacrificial material 320 can include etching sacrificial material 320 at a first etch rate, and catching dielectric liner 306 at a second etch rate with a same etchant, where the first etch rate is greater than the second etch rate. By etching sacrificial material 320 at a greater etch rate than dielectric liner 306, portions of dielectric sidewalls 314 are gradually exposed and exposed portions of dielectric liner 306 are gradually thinned, such that dielectric liner 306 is tapered. Thus, tapered dielectric liner 306 includes slanted dielectric sidewalls 414, while trench 404 includes slanted dielectric sidewalls 414.

As shown, the etching of sacrificial material 320 and dielectric liner 306 can continue to form dielectric liner 406 as a tapered dielectric liner for a semiconductor device having slanted dielectric sidewalls 414. In some implementations, the etching of sacrificial material 320 at the first etch rate can be from approximately 10 to approximately 50 times faster than the etching of dielectric liner 306 at the second etch rate. The first and second etch rates of sacrificial material 320 and dielectric liner 306 can be substantially constant throughout. However, the different etch rates of sacrificial material 320 and dielectric liner 306 can be adjusted during the etching of sacrificial material 320 and dielectric liner 306 thereby adjusting a slope of dielectric sidewalls 314 of dielectric liner 306. For example, various parameters of the etching can be adjusted so as to adjust the slope. Thus, while tapering of dielectric sidewalls 314 of dielectric liner 306 has resulted in slanted dielectric sidewalls 414 having a substantially constant slope, in other implementations, dielectric sidewalls 414 can be contoured as desired.

The etching of dielectric liner 306 and sacrificial material 320 can include an isotropic etching of sacrificial material 320. Suitable etching technologies include various forms of reactive-ion etching (RIE) and plasma etching.

The etching of sacrificial material 320 and dielectric liner 306 can continue until dielectric liner 406 tapers into bottom 410 of trench 404, which is a rounded bottom, as shown. The etching of sacrificial material 320 and dielectric liner 306 can continue until substantially all of sacrificial material 320 is removed from trench 304. However, in some implementations, the etching of sacrificial material 320 and dielectric liner 306 ends with sacrificial material 420 still in trench 404, which is a remaining bottom portion of sacrificial material 320.

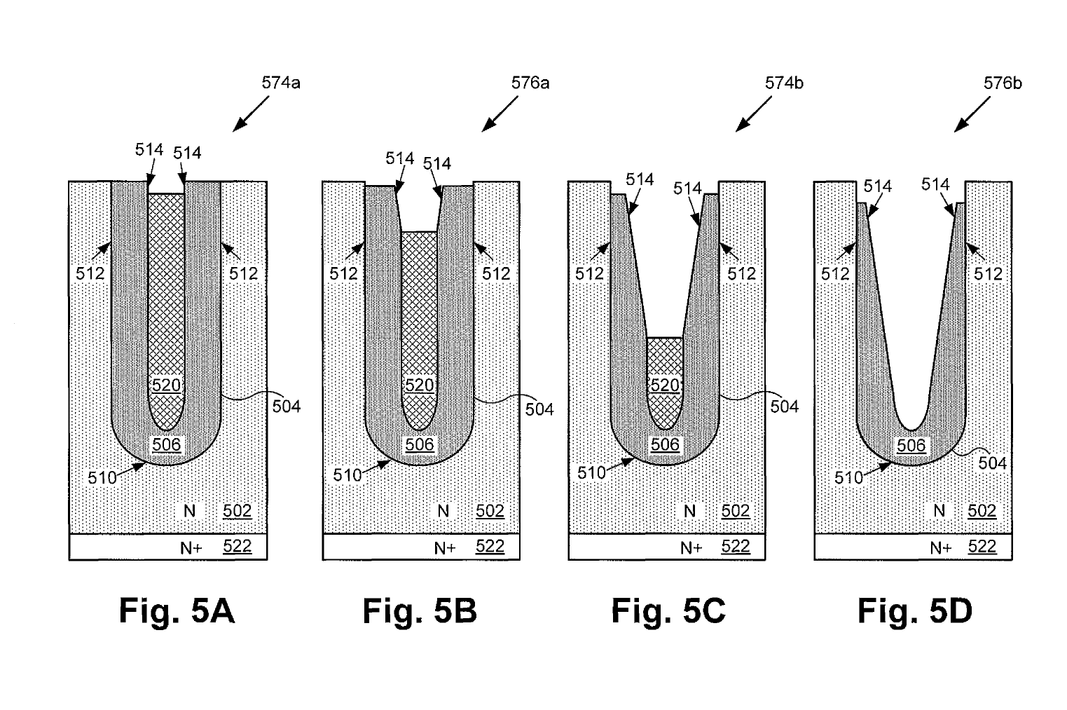

A second approach to processing semiconductor structure 370 of FIG. 3 so as to taper dielectric liner 306 is shown and described below with respect to actions 274, 276 and 286 of flowchart 200 in FIG. 2 and FIGS. 5A, 5B, and 5C.

Referring to flowchart 200 of FIG. 2 and to FIGS. 3 and 5A, action 274 of flowchart 200 includes using a first etchant to etch the sacrificial material (e.g., 320) faster than the dielectric liner (e.g., 306).

FIG. 5A illustrates a cross-sectional view, which includes a portion of an exemplary semiconductor structure, processed according to an implementation disclosed in the present application. In particular, FIG. 5A shows semiconductor structure 574a, which includes drift region 502, trench 504, dielectric liner 506, sacrificial material 520, and drain region 522.

In FIG. 5A, semiconductor structure 574a, trench 504, dielectric liner 506, and sacrificial material 520, and drift region 502 correspond respectively to semiconductor structure 372, trench 304, dielectric liner 306, sacrificial material 320, and drift region 302 after using a first etchant to etch sacrificial material 320 faster than dielectric liner 306. Etching sacrificial material 320 faster than dielectric liner 306 results in exposed portions of dielectric sidewalls 514 of dielectric liner 506. In some implementations, using a first etchant to etch sacrificial material 320 faster than dielectric liner 306 is performed without substantially etching dielectric liner 306. Suitable etching technologies include various forms of vapor or liquid phase etching.

Referring to flowchart 200 of FIG. 2 and to FIGS. 5A and 5B, action 276 of flowchart 200 includes using a second etchant to etch the dielectric liner (e.g., 506) faster than the sacrificial material (e.g., 520).

FIG. 5B illustrates a cross-sectional view, which includes a portion of an exemplary semiconductor structure, processed according to an implementation disclosed in the present application. In particular, FIG. 5B shows semiconductor structure 576a, which corresponds to semiconductor structure 574a of FIG. 5A after using a second etchant to etch dielectric liner 506 faster than sacrificial material 520.

In some implementations, using a second etchant to etch dielectric liner 506 faster than sacrificial material 520 is performed without substantially etching sacrificial material 520. For example, after using a first etchant to etch the sacrificial material (e.g., 320) faster than the dielectric liner (e.g., 306) (action 274 of flowchart 200 in FIG. 2) to result in semiconductor structure 574a, semiconductor structure 574a may no longer be exposed to the first etchant while being exposed to the second etchant. The using of the second etchant to etch dielectric liner 506 faster than sacrificial material 520 can include an isotropic etching of dielectric liner 506. Suitable etching technologies include various forms of vapor or liquid phase etching.

As indicated by action 286 in FIG. 2, the forgoing can be repeated over multiple iterations, thereby alternating between the using of the first etchant (action 274 of flowchart 200 in FIG. 2) and the using of the second etchant (action 276 in FIG. 2). In some implementations, the first etchant and the second etchant are consecutively used. In other implementations, other etchants can be used between the using of the first etchant and the using the second etchant. Furthermore, respective etch rates and etch times of sacrificial material 520 and dielectric liner 506 may be altered or may be substantially constant throughout the multiple iterations.

The multiple iterations can be, for example, between approximately 5 and approximately 50 iterations. It is noted that the multiple iterations may end with either the using of the first etchant (action 274 of flowchart 200 in FIG. 2) or the using of the second etchant (action 276 of flowchart 200 in FIG. 2). Where the multiple iterations is, for example, approximately 20, FIG. 5B can correspond to semiconductor structure 372 of FIG. 3 after approximately 4 iterations. As can be seen in FIG. 5B, by utilizing the multiple iterations, dielectric liner 506 is gradually tapered.

Referring to FIG. 5C, FIG. 5C illustrates a cross-sectional view, which includes a portion of an exemplary semiconductor structure, processed according to an implementation disclosed in the present application. In particular, FIG. 5C shows semiconductor structure 574b, which corresponds to semiconductor structure 576a of FIG. 5B after approximately 12 iterations, or to semiconductor structure 372 of FIG. 3 after approximately 16 iterations.

Referring to flowchart 200 of FIG. 2 and to FIGS. 4A, 4B, 5C, and 5D, action 278 of flowchart 200 includes optionally removing a remaining bottom portion (e.g., 420, 520) of the sacrificial material from a bottom (e.g., 410, 510) of the trench (e.g., 404, 504).

FIG. 5D illustrates a cross-sectional view, which includes a portion of an exemplary semiconductor structure, processed according to an implementation disclosed in the present application. In particular, FIG. 5D shows semiconductor structure 576b, which corresponds to semiconductor structure 574b of FIG. 5C after approximately 4 iterations, or to semiconductor structure 372 of FIG. 3 after approximately 20 iterations. As can be seen in FIG. 5D, sacrificial material 520 has been completely removed from bottom 510 of trench 504. After removing sacrificial material 520 from bottom 510 of trench 504, a clean may be performed on semiconductor structure 576b as desired.

FIG. 4B illustrates a cross-sectional view, which includes a portion of an exemplary semiconductor structure, processed according to an implementation disclosed in the present application. In particular, FIG. 4B shows semiconductor structure 478, which corresponds to semiconductor structure 472 after removing sacrificial material 420 from bottom 410 of trench 404. In some implementations, sacrificial material 420 is removed from bottom 410 of trench 404 by etching sacrificial material 420 without substantially etching dielectric liner 406. In other implementations, sacrificial material 420 is removed from bottom 410 of trench 404 during the etching described above with respect to FIGS. 3 and 4A (action 272 of flowchart 200 in FIG. 2). After removing sacrificial material 420 from bottom 410 of trench 404, a clean may be performed on semiconductor structure 478 as desired.

As described above, the remaining bottom portion of the sacrificial material is optionally removed from trenches 404 and 504. However, in some implementations at least some of the remaining bottom portion of the sacrificial material in trench 404 or trench 504 remains throughout fabrication of a semiconductor device. The remaining bottom portion of the sacrificial material can be retained by a fabricated semiconductor device to form various features of the fabricated semiconductor device. For example, the remaining bottom portion of the sacrificial material may be retained as part of a thicker bottom dielectric in trench 404 or trench 504 than respective dielectric liners 406 and 506 alone.

Referring to flowchart 200 of FIG. 2 and to FIGS. 1 and 4B and 5D, action 280 of flowchart 200 includes forming a semiconductor device (e.g., 100) having a conductive filler (e.g., 108) within the trench (e.g., 104) and enclosed by the tapered dielectric liner (e.g., 106).

Semiconductor structure 100 in FIG. 1 corresponds to semiconductor structure 478 of FIG. 4B or to semiconductor structure 576b of FIG. 5D after having formed a semiconductor device having conductive filler 108 within trench 104 and enclosed by tapered dielectric liner 106. Thus, drain region 122, drift region 102, trench 104, and dielectric liner 106 in FIG. 1 can correspond to drain region 422, drift region 402, trench 404, and tapered dielectric liner 406 in FIG. 4B. Furthermore, drain region 122, drift region 102, trench 104, and tapered dielectric liner 106 in FIG. 1 can correspond to drain region 522, drift region 502, trench 504, and tapered dielectric liner 506 in FIG. 5.

In the present implementation, conductive filler 108 is an electrode of the semiconductor device that is electrically insulated from drift region 102 by tapered dielectric liner 106. Conductive filler 108 can be formed in trench 104 by depositing polysilicon or metal over semiconductor structure 478 of FIG. 4B or semiconductor structure 576b of FIG. 5D and within trench 104. The polysilicon can be doped in-situ or ex-situ. Due to slanted dielectric sidewalls 114 of tapered dielectric liner 106 in trench 104, conductive filler 108 has a significantly reduced risk of being formed with voids and/or other defects. Thus, trench 104 may be made narrower thereby reducing cell pitch of semiconductor structure 100 and reducing on-resistance.

The semiconductor device can be selected from various types of semiconductor devices including a diode, a FET, and more generally a semiconductor device that includes a trench having a dielectric liner. In the implementation shown, semiconductor structure 100 includes a FET, and more particularly a trench FET having gate electrodes 130a and 130b, gate dielectric liners 132a and 132b, body regions 134a, 134b, 134c, and 134d, source regions 136a, 136b, 136c and 136d, dielectric caps 138a and 138b, source contact 140, and drain contact 142, in addition to other features previously described. Body regions 134a, 134b, 134c, and 134d and source regions 136a, 136b, 136c and 136d can be formed in drift region 102 by doping regions of drift region 102 to be P type and N+ type, respectively.

Also in the present implementation, conductive filler 108 is a field plate that is formed in trench 104. Conductive filler 108 is electrically coupled to source contact 140, which can include metal. Furthermore, dielectric caps 138a and 138b are configured to electrically insulate gate electrodes 130a and 130b from source contact 140. A conduction channel can be formed between source contact 140 and drain contact 142, which are on opposing sides of semiconductor structure 100. In this respect, semiconductor structure 100 can be considered a vertical conduction semiconductor device. Where semiconductor structure 100 is instead a diode, semiconductor structure 100 can be a vertical conduction semiconductor device in which a conduction channel can be formed between an anode contact and a cathode contact on opposing sides of semiconductor structure 100. Furthermore, conductive filler 108 can be an anode electrode of the diode. In addition to, or instead of providing for a field plate (e.g., 108) enclosed by a dielectric liner that is tapered, implementations of the present disclosure can provide for formation of a gate electrode (e.g., 130a, 130b), in a similarly constructed trench, enclosed by a gate dielectric liner (e.g., 132a, 132b) that may tapered utilizing any of the methods described with respect to FIG. 2.

In the present implementations, conductive filler 108 has tapered sidewalls that are substantially parallel to respective slanted dielectric sidewalls 114 of tapered dielectric liner 106. When semiconductor structure 100 is in reverse bias, conductive filler 108 can be at a source potential of approximately 0 volts. Drain contact 142 can be at a drain potential of, for example, approximately 100 volts. At bottom 110 of trench 104, tapered dielectric liner 106 is thicker so as to better support approximately the full drain potential. However, the electric potential that tapered dielectric liner 106 must support gradually decreases toward source contact 140. Thus, tapered dielectric liner 106 can gradually decrease in thickness toward source contact 140 and still support the electric potential. Thus, the effectiveness of conductive filler 108 as a field plate can be enhanced by including tapered dielectric liner 106. As such, drift region 102 can be more heavily doped, resulting in lower R_{DSON} of semiconductor structure 100. Moreover, the semiconductor device breakdown voltage, i.e. its reverse voltage blocking capability, is also improved.

Thus, as described above with respect to FIGS. 1, 2, 3, 4A, 4B, 5A, 5B, 5C, and 5D, implementations of the present disclosure provide for formation of a tapered dielectric liner in a trench in a drift region. The trench may have substantially parallel trench sidewalls. Furthermore, the dielectric liner has slanted dielectric sidewalls that are not parallel. As such, the risk that voids or other defects form when depositing conductive filler in the trench is significantly reduced, which allows for the trench to be made narrower. Thus, formation of the trench may avoid processing constraints which might otherwise dictate the shape of the trench.

From the above description it is manifest that various techniques can be used for implementing the concepts described in the present application without departing from the scope of those concepts. Moreover, while the concepts have been described with specific reference to certain implementations, a person of ordinary skill in the art would recognize that changes can be made in form and detail without departing from the scope of those concepts. As such, the described implementations are to be considered in all respects as illustrative and not restrictive. It should also be understood that the present application is not limited to the particular implementations described above, but many rearrangements, modifications, and substitutions are possible without departing from the scope of the present disclosure.

1. A semiconductor structure comprising:
a trench having substantially parallel trench sidewalls;
a tapered dielectric liner in said trench, said tapered dielectric liner having slanted dielectric sidewalls;
a conductive filler enclosed by said slanted dielectric sidewalls.

2. The semiconductor structure of claim 1, wherein said conductive filler is a field plate in a power transistor.

3. The semiconductor structure of claim 1, wherein said trench is situated in a drift region of a power transistor.

4. The structure of claim 1, wherein said tapered dielectric liner comprises silicon oxide.

5. The structure of claim 1, wherein said conductive filler comprises polysilicon.

6. The semiconductor structure of claim 1, wherein said semiconductor structure is part of a power transistor.

7. The semiconductor structure of claim 6, wherein said power transistor in a vertical conduction semiconductor device.

8. A method comprising:
forming a trench in a semiconductor structure;
forming a dielectric liner in said trench;
forming a sacrificial material covering said dielectric liner;
etching said sacrificial material with an etchant at a first etch rate while etching said dielectric liner with said etchant at a second etch rate, thereby producing a tapered dielectric liner having slanted dielectric sidewalls.

9. The method of claim 8, further comprising depositing a conductive filler in said trench, said conductive filler being enclosed by said slanted dielectric sidewalls.

10. The method of claim 8, wherein said first etch rate is greater than said second etch rate.

11. The method of claim 8, wherein said slanted dielectric sidewalls have a substantially constant slope.

12. The method of claim 8, wherein said etching said dielectric liner with said etchant at said second etch rate comprises an isotropic etching of said sacrificial material.

13. The method of claim 8, wherein said sacrificial material comprises an organic material.

14. The method of claim 8, wherein said dielectric liner comprises silicon oxide.

15. The method of claim 9, wherein said conductive filler comprises polysilicon.

16. A method comprising:
forming a trench in a semiconductor structure;
forming a dielectric liner in said trench;
forming a sacrificial material covering said dielectric liner;
etching, with a first etchant, said sacrificial material and said dielectric liner;
etching, with a second etchant, said sacrificial material and said dielectric liner, thereby producing a tapered dielectric liner having slanted dielectric sidewalls.

17. The method of claim 16, wherein said dielectric liner comprises silicon oxide.

18. The method of claim 16, wherein said etching with said second etchant comprises an isotropic etching of said dielectric liner.

19. The method of claim 16, wherein said etching with said first etchant is performed without substantially etching said dielectric liner.

20. The method of claim 16, wherein said etching with said second etchant is performed without substantially etching said sacrificial material.
